(19) United States
(12) Patent Application Publication
(10) Pub. No.: US 2021/0042236 A1
(43) Pub. Date: Feb. 11, 2021

(54) WEAR LEVELING ACROSS BLOCK POOLS

(71) Applicant: Micron Technology, Inc., Boise, ID (US)

(72) Inventor: Giuseppe CARIELLO, Boise, ID (US)

(21) Appl. No.: 16/533,673

(22) Filed: Aug. 6, 2019

(51) Int. Cl. G06F 12/0895

(52) U.S. Cl. CPC G06F 12/0895; G06F 2212/608; G06F 2212/1036

(57) ABSTRACT

Systems and methods to wear level block pools include a memory component and a processing device coupled to the memory component. The processing device allocates a single-level cell cache across both a first pool of low-density cells and a second pool of high-density cells, determines a difference in normalized wear between the first and second pools satisfies a wear threshold criterion, and prioritizes the second pool for a single-level cell write to the cache in response to the difference in normalized wear satisfying the wear threshold criterion.

### TECHNICAL FIELD

The present disclosure generally relates to memory block pools, and more specifically, relates to wear leveling across block pools.

### BACKGROUND ART

A memory sub-system can be a storage system, a memory module, or a hybrid of a storage device and memory module. The memory sub-system can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing environment that includes a memory subsystem in accordance with some embodiments of the present disclosure.

FIG. 2 is a flow diagram of an example method to wear level across block pools in accordance with some embodiments of the present disclosure.

FIG. 3 is a block diagram of an example computer system in which embodiments of the present disclosure may operate.

### DETAILED DESCRIPTION

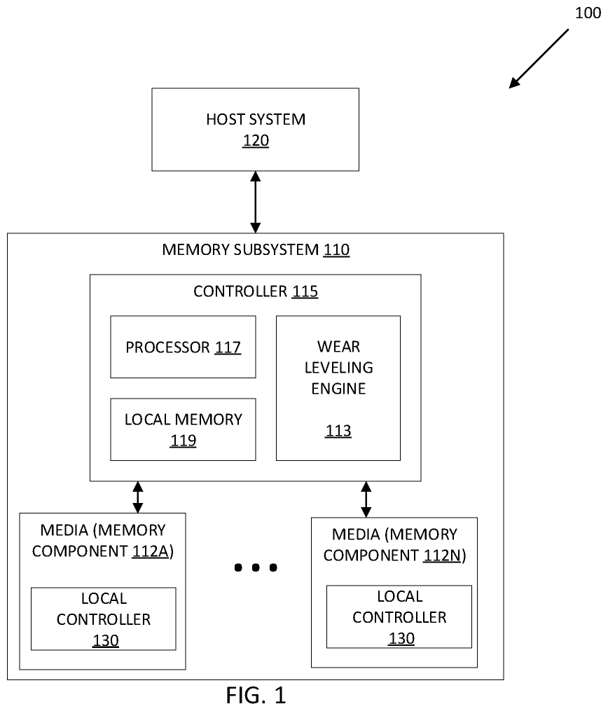

Aspects of the present disclosure are directed to wear leveling across block pools in a memory subsystem. A memory sub-system can be a storage device, a memory module, or a hybrid of a storage device and memory module. Examples of storage devices and memory modules are described below in conjunction with FIG. 1. In general, a host system can utilize a memory subsystem that includes one or more memory devices that store data. The host system can provide data to be stored at the memory subsystem and can request data to be retrieved from the memory subsystem.

The memory devices can be raw memory devices (e.g., NAND), which are managed externally, for example, by an external controller. An example of an external controller is described in greater detail below in conjunction with FIG. 1. The memory devices can be managed memory devices (e.g., managed NAND), which is a raw memory device combined with a local controller for memory management within the same memory device package. An example of a local controller is described in greater detail below in conjunction with FIG. 1.

A non-volatile memory device is a package of one or more dice. Each die can be comprised of one or more planes. For some types of non-volatile memory devices (e.g., NAND devices), each plane is a set of physical blocks, and each block is a set of pages. Each page is a set of memory cells, where each cell is an electronic circuit that stores bit(s) of data.

The memory cells can be as single level cells (SLCs), multi-level cells (MLCs), triple level cells (TLCs), and quad-level cells (QLCs), storing a corresponding number of bits per cell. In some embodiments, a particular memory device can include one or more portions dedicated to a particular memory cell type. For example, a memory device may have one portion of SLC and another portion of MLC, TLC, or QLC.

In conventional systems, blocks arranged in a memory device (e.g., NAND flash memory device) can be divided into one or more block pools. The pools can include SLCs, MLCs, TLCs, and QLCs.

Writing a block having MLCs, TLCs, or QLCs is typically slower when compared to writing to a block having SLCs. To obtain better performance, memory sub-systems typically include a cache made of SLC memory (hereinafter referred to as “SLC cache”), whose stored data is transferred to MLC, TLC, and/or QLC memory when idle time permits.

The storing of data at a memory device can increase the wear of the memory device. After a certain amount of write operations to a memory device, the wear can gradually cause the memory device to become unreliable, such that data can no longer be reliably stored and retrieved from the memory device. At such a point, the memory sub-system can result in a failure when any of the memory devices fail.

To reduce wear within a block pool, conventional systems typically utilize wear leveling techniques. Wear leveling is a process that helps reduce premature wear in memory devices by distributing write operations across the memory devices. Wear leveling includes a set of operations to ensure that certain physical blocks of memory are not written and erased more often than others. There are two types of wear leveling techniques: dynamic wear leveling, that selects the next block where write to, and static wear leveling, that moves cold data (the one less likely to be overwritten or erased) to the most worn out blocks. These conventional systems, however, are unable to compensate asymmetric wear across block pools. For example, different usage models can wear out the SLC block pool faster than the MLC block pool, or vice versa. This because moving blocks from one pool to the other is generally prohibited due to the different wear out effect caused to the block by different program and erase operation (SLC vs MLC vs TLC etc.).

Aspects of the present disclosure address the above and other deficiencies by implementing wear leveling across block pools. As described herein, the memory sub-system can include a wear leveling engine that allocates an SLC cache using blocks from any of the pools (e.g., both the SLC and MLC pools) and prioritizes write operations to one block pool or the other based upon the wear on each pool. As a result, the wear of the block pools is distributed evenly.

FIG. 1 illustrates an example computing environment 100 that includes a memory subsystem 110 in accordance with some embodiments of the present disclosure. The memory subsystem 110 can include media, such as memory components 112A to 112N. The memory components 112A to 112N can be volatile memory components, non-volatile memory components, or a combination of such. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory subsystem 110 so that the host system 120 can read data from or write data to the memory subsystem 110. The host system 120 can be coupled to the memory subsystem 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 120 and the memory subsystem 110. The host system 120 can further utilize an NVM Express (NVMe) interface to access the memory components 112A to 112N when the memory subsystem 110 is coupled with the host system 120 by the PCIe interface. The physical host interface can provide an interface for passing control, address, data, and other signals between the memory subsystem 110 and the host system 120.

The memory components 112A to 112N can include any combination of the different types of non-volatile memory components and/or volatile memory components. An example of non-volatile memory components includes a negative-and (NAND) type flash memory. Each of the memory components 112A to 112N can include one or more arrays of memory cells, such as (SLCs or cells that store more than one bit, e.g., triple-level cells (TLCs) or quad-level cells (QLCs)). In some embodiments, a particular memory component can include both an SLC portion and an MLC portion of memory cells. Each of the memory cells can store one or more bits of data (e.g., data blocks) used by the host system 120. Although non-volatile memory components such as NAND type flash memory are described, the memory components 112A to 112N can be based on any other type of memory such as a volatile memory. In some embodiments, the memory components 112A to 112N can be, but are not limited to, random access memory (RAM), read-only memory (ROM), dynamic random access memory (DRAM), synchronous dynamic random access memory (SDRAM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. Furthermore, the memory cells of the memory components 112A to 112N can be grouped as memory pages or data blocks that can refer to a unit of the memory component used to store data.

The memory system controller 115 (hereinafter referred to as “controller”) can communicate with the memory components 112A to 112N to perform operations such as reading data, writing data, or erasing data at the memory components 112A to 112N and other such operations. The controller 115 can include hardware such as one or more integrated circuits and/or discrete components, a buffer memory, or a combination thereof. The controller 115 can be a microcontroller, special purpose logic circuitry (e.g., a field programmable gate array (FPGA), an application specific integrated circuit (ASIC), etc.), or another suitable processor. The controller 115 can include a processor (processing device) 117 configured to execute instructions stored in local memory 119. In the illustrated example, the local memory 119 of the controller 115 includes an embedded memory configured to store instructions for performing various processes, operations, logic flows, and routines that control operation of the memory subsystem 110, including handling communications between the memory subsystem 110 and the host system 120. In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the controller 115, in another embodiment of the present disclosure, a memory subsystem 110 may not include a controller 115, and may instead rely upon external control (e.g., provided by an external host, or by a processor or controller separate from the memory subsystem).

In general, the controller 115 can receive commands or operations from the host system 120 and can convert the commands or operations into instructions or appropriate commands to achieve the desired access to the memory components 112A to 112N. The controller 115 can be responsible for other operations such as wear leveling operations, garbage collection operations, error detection and error-correcting code (ECC) operations, encryption operations, caching operations, and address translations between a logical block address and a physical block address that are associated with the memory components 112A to 112N. The controller 115 can further include host interface circuitry to communicate with the host system 120 via the physical host interface. The host interface circuitry can convert the commands received from the host system into command instructions to access the memory components 112A to 112N as well as convert responses associated with the memory components 112A to 112N into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the controller 115 and decode the address to access the memory components 112A to 112N.

The memory subsystem 110 includes a wear leveling engine 113 that manages wear leveling across block pools. In some embodiments, the controller 115 includes at least a portion of the wear leveling engine 113. For example, the controller 115 can include a processor 117 (processing device) configured to execute instructions stored in local memory 119 for performing the operations described herein. In some embodiments, the wear leveling engine 113 is part of the host system 110, an application, or an operating system.

In some embodiments, the memory components 112A to 112N can be managed memory devices (e.g., managed NAND), which is a raw memory device combined with a local controller 130 for memory management within the same memory device package. A local controller 130 can include a wear leveling engine 113.

The wear leveling engine 113 can allocate an SLC cache across multiple pools of different cell types (e.g., a pool of SLCs, a pool of MLCs, a pool of TLCs, etc.). As used herein, “pool” refers to a set of blocks that make up non-volatile memory components (e.g., NAND devices, managed NAND devices, etc.). In some embodiments, one pool has a higher bit density than another pool. For example, an SLC cache may be allocated across an SLC pool and an MLC pool. The SLC cache can be made of a static portion and a dynamic portion, and the pools can be configured for the different portions of the SLC cache. For example, the SLC pool can be configured as the static SLC portion, and the MLC pool can be configured as the dynamic SLC portion (i.e., MLCs programmed as SLCs). The pools can be configured to store different types of data. For example, the SLC pool may store system data, such as system tables, and the MLC pool may store host data. Other embodiments can include different allocations of the pools.

The wear leveling engine 113 determines if a difference in normalized wear between the pools satisfies a threshold criterion (e.g., greater than a wear threshold) and directs write operations to the pools accordingly. In some embodiments, the wear leveling engine 113 prioritizes/directs write operations to the high-density pool in response to the difference in normalized wear between the pools satisfying the threshold criterion (e.g., exceeding the wear threshold). Further details with regards to the operations of the cross-wear engine 113 are described below.

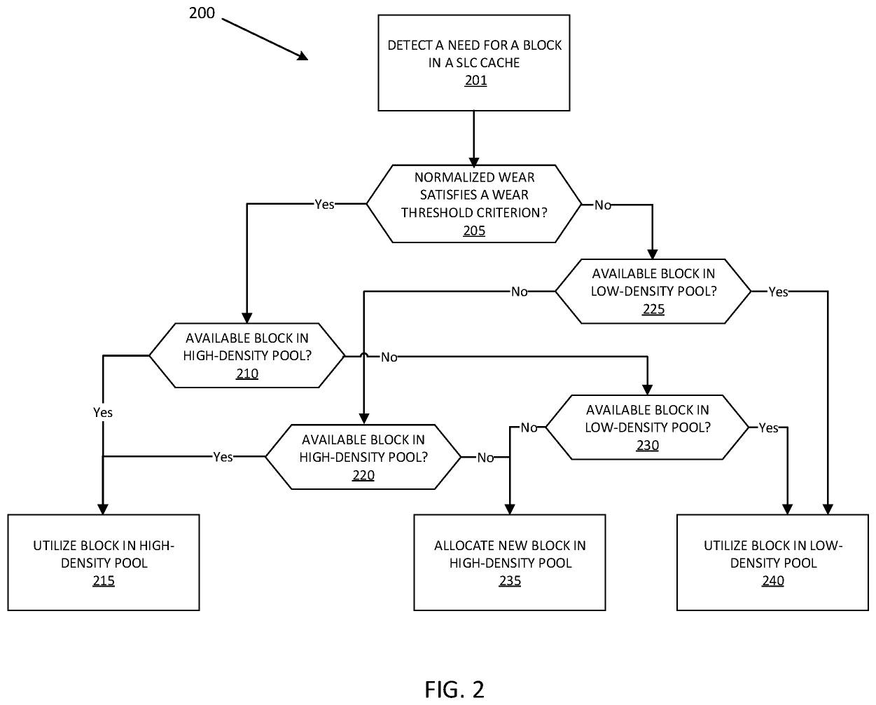

FIG. 2 is a flow diagram of an example method 200 to wear level across block pools, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the wear leveling engine 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 201, the processing device detects a need for a block in a single level cell (SLC) cache (e.g., a SLC cache block). For example, the memory subsystem 110 performs a read or write operation for the host system 120 that results in writing data to the SLC cache. Writing data to the SLC cache triggers a need for one or more SLC cache blocks.

As described above, the processing device allocates portions of the SLC cache across multiple pools. In some embodiments, the pools have a different bit density. For example, the processing device can allocate one portion of a SLC cache across a low-density pool (e.g., a pool of single-level cells) and another portion of the SLC cache across a high-density pool (e.g., a pool of multi-level cells, triple-level cells, or quad-level cells). While the examples below reference SLCs for the low-density pool, other embodiments can include another density of cells that is lower than the high-density pool (e.g., a low-density pool of MLCs and high-density pool of TLCs).

In one embodiment, the portion of the SLC cache allocated in the low-density pool is a static SLC cache. For example, the static SLC cache portion is allocated a pool of blocks that are maintained in a static bit density state—e.g., the blocks remain as SLC blocks and are not used in another density state such as MLC or TLC. In one embodiment, the portion of the single level cell cache allocated in the high-density pool is a dynamic SLC cache. For example, the dynamic SLC cache has a dynamic size (e.g., a variable size generated or otherwise determined in real-time, or near real-time) and the bit density of blocks used for the dynamic SLC cache varies (e.g., from TLC to SLC for use in the SLC cache). In such embodiments, the processing device can allocate/repurpose an MLC block available to a host partition for use as an SLC cache block when all allocated blocks within the dynamic SLC cache are in use, thereby increasing the size of the SLC cache as needed. Similarly, the processing device can release a block in the dynamic SLC cache for use by the host partition when the block is no longer in use by the SLC cache.

In fulfilling the detected need for a SLC cache block, the processing device determines whether to utilize or allocate a block from the low-density pool or the high-density pool. For example, the processing device uses a wear leveling scheme based upon normalized wear to prioritize one or the other pool as described below.

At operation 205, the processing device determines if a difference in wear between the low-density and high-density pools satisfies a wear threshold criterion (e.g., the difference is greater than or equal to a wear threshold). In one embodiment, the difference in wear is determined based on program/erase (P/E) cycle counts for the pools. In another embodiment, the processing device uses another indication of wear, such as a count of writes, erases, or another activity that correlates with the degradation of memory components.

In one embodiment, the wear counts are normalized counts. For example, a low-density pool can have a greater endurance threshold than a high-density pool. As a result, the processing device utilizes normalized counts to compare wear between pools. The normalization can include using a current wear count as a fraction of a total expected wear count for a pool. For example, a low-density pool with a current count of 30k average P/E cycles and an expected lifetime endurance of 60k P/E cycles would have a normalized P/E cycle count of 0.5. As a result, the comparison of wear between pools is based upon the percentage of total wear each pool can endure. In another embodiment, the processor normalizes wear counts using a factor representing the difference in endurance between the pools. As such, if the high-density pool wears out twice as fast as the low-density pool, a normalized count can double the actual wear count for the high-density pool.

In one embodiment, the difference in normalized wear between pools is determined according to the following algorithm: NPE_{SLC}—NPE_{MLC}, wherein NPE_{SLC} is a Normalized Program Erase cycle count for the low-density pool and NPE_{MLC} is a Normalized Program Erase cycle count for the high-density pool. In other embodiments, the difference in normalized wear is determined according to another algorithm.

In one embodiment, the wear threshold criterion is a value indicative of imbalance in wear between the low-density and high-density pools. For example, the wear threshold may be indicative of the relative age difference of the two pools. In the illustrated embodiment, in which the low-density pool of blocks is typically subject to greater wear, responsive to the difference in the normalized wear satisfying the wear threshold criterion, the processing device implements wear leveling across the low-density and high-density pools by prioritizing the high-density pool for the utilization or allocation of a block for a write operation directed to the SLC cache. In another embodiment in which the high-density pool of blocks is typically subject to greater wear (not shown in FIG. 2), the processing device can prioritize the low-density pool. As a result, the block pools wear more evenly and the life of the memory subsystem 110 is increased.

If the difference in normalized wear between the low-density and high-density pools satisfies the wear threshold criterion (e.g., is greater than or equal to a wear threshold), the method 200 proceeds to operation 210 to prioritize the high-density pool for the utilization or allocation of a block. At operation 210, the processing device determines if the high-density pool includes an available block allocated to the SLC cache. If the high-density pool includes an available block allocated to the SLC cache, the processing device utilizes the available block in the high-density pool at operation 215. As a result, the processing device responds to the normalized wear satisfying the wear threshold criterion (e.g., exceeding) by prioritizing writes to the high-density pool.

If the high-density pool does not include an available block allocated to the SLC cache (at operation 210), the processing device determines if the low-density pool includes an available block allocated to the SLC cache at operation 230. If the low-density pool also does not include an available block allocated to the SLC cache, the processing device determines that the SLC cache is full and, at operation 235, it opens, or otherwise allocates, a new block in the high-density pool that was previously unallocated or allocated for another usage (e.g., allocated for the storage of host data). If a free block is available in the high-density portion of the memory subsystem 110, the processing device can repurpose that block by allocating it to the dynamic portion of the SLC cache.

At operation 240, if the high-density pool does not include an available block but the low-density pool does include an available block (at operation 230), the processing device utilizes the available block in the low-density pool to minimize latency in writing to the SLC cache.

If the difference in normalized wear does not satisfy the wear threshold criterion (e.g., is less than or equal to the wear threshold criterion) at operation 205 (indicating that there is not currently an unacceptable imbalance in wear across the pools), the processing device determines if the low-density pool includes an available block allocated to the SLC cache at operation 225. If there is an available block in the low-density pool, the processing device utilizes the available block for the write to the SLC cache at operation 240.

If the processing device determines that the low-density pool does not include an available block allocated to the SLC cache at operation 225, the processing device determines if the high-density pool includes an available block at operation 220 and utilizes an available block at operation 215 or allocates a new block in the high-density pool at operation 235, as described above.

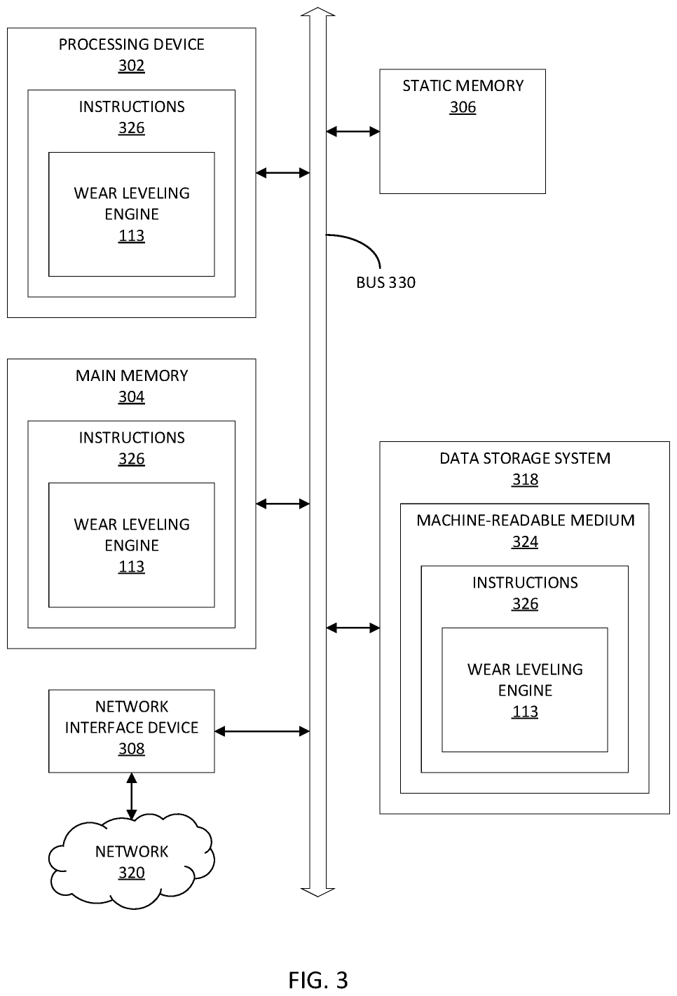

FIG. 3 illustrates an example machine of a computer system 300 within which a set of instructions, for causing the machine to perform any one or more of the methodologies discussed herein, can be executed. In some embodiments, the computer system 300 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the cross-wear engine 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 300 includes a processing device 302, a main memory 304 (e.g., read-only memory (ROM), flash memory, dynamic random access memory (DRAM) such as synchronous DRAM (SDRAM) or Rambus DRAM (RDRAM), etc.), a static memory 306 (e.g., flash memory, static random access memory (SRAM), etc.), and a data storage system 318, which communicate with each other via a bus 330.

Processing device 302 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 302 can also be one or more special-purpose processing devices such as an application specific integrated circuit (ASIC), a field programmable gate array (FPGA), a digital signal processor (DSP), network processor, or the like. The processing device 302 is configured to execute instructions 326 for performing the operations and steps discussed herein. The computer system 300 can further include a network interface device 308 to communicate over the network 320.

The data storage system 318 can include a machine-readable storage medium 324 (also known as a computer-readable medium) on which is stored one or more sets of instructions 326 or software embodying any one or more of the methodologies or functions described herein. The instructions 326 can also reside, completely or at least partially, within the main memory 304 and/or within the processing device 302 during execution thereof by the computer system 300, the main memory 304 and the processing device 302 also constituting machine-readable storage media. The machine-readable storage medium 324, data storage system 318, and/or main memory 304 can correspond to the memory subsystem 110 of FIG. 1.

In one embodiment, the instructions 326 include instructions to implement functionality corresponding to a cross-wear engine component (e.g., the cross-wear engine 113 of FIG. 1). While the machine-readable storage medium 324 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented method 200 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
allocating a single-level cell (SLC) cache across both a first pool of low-density cells and a second pool of high-density cells;
determining a difference in normalized wear between the first and second pools satisfies a wear threshold criterion; and
prioritizing the second pool for a first write operation in response to the difference in normalized wear satisfying the wear threshold criterion.

2. The method of claim 1, wherein prioritizing the second pool comprises determining if the second pool includes an available block allocated to the SLC cache.

3. The method of claim 2, wherein the available block is utilized in the second pool if the second pool includes the available block allocated to the SLC cache.

4. The method of claim 2, wherein prioritizing the second pool comprises:
determining if the first pool includes an available block allocated to the SLC cache; and
allocating another block to the second pool for the SLC write in response to determining the second pool and the first pool do not include the available block.

5. The method of claim 2, wherein prioritizing the second pool comprises utilizing an available block in the first pool in response to determining the second pool does not include the available block.

6. The method of claim 1, wherein a portion of the SLC cache allocated in the first pool has a static size, and wherein the portion of the SLC cache allocated in the second pool has a dynamic size.

7. The method of claim 1, wherein the difference in normalized wear is determined based on a normalized program erase cycle count for the first pool and a normalized program erase cycle count for the second pool.

8. The method of claim 1, further comprising:
determining the difference in the normalized wear between the first and second pools satisfies a second wear threshold criterion; and
prioritizing the first pool for a second SLC write in response to the difference in normalized wear satisfying the second wear threshold criterion.

9. The method of claim 8, wherein prioritizing the first pool comprises:
determining if the first pool includes an available block allocated to the SLC cache; and
utilizing an available or newly allocated block in the second pool in response to determining the first pool does not include an available block.

10. The method of claim 8, wherein prioritizing the first pool comprises utilizing an available block in the first pool.

11. A non-transitory computer-readable storage medium comprising instructions that, when executed by a processing device, cause the processing device to:
allocate a single-level cell (SLC) cache across both a first pool of low-density cells and a second pool of high-density cells;
determine a difference in normalized wear between the first and second pools satisfies a wear threshold criterion; and
prioritizing the second pool for a first SLC write in response to the difference in normalized wear satisfying the wear threshold criterion.

12. The non-transitory computer-readable medium of claim 11, wherein prioritizing the second pool comprises determining if the second pool includes an available block allocated to the SLC cache.

13. The non-transitory computer-readable medium of claim 12, wherein the available block is utilized in the second pool if the second pool includes the available block allocated to the SLC cache.

14. The non-transitory computer-readable medium of claim 12, wherein prioritizing the second pool includes allocating another block to the second pool for the SLC write in response to determining the second pool and the first pool do not include the available block.

15. The non-transitory computer-readable medium of claim 12, wherein prioritizing the second pool includes utilizing an available block in the first pool in response to determining the second pool does not include the available block.

16. A system comprising:
a memory component; and
a processing device, coupled to the memory component, configured to:
allocate a single-level cell (SLC) cache across both a first pool of low-density cells and a second pool of high-density cells, wherein a portion of the SLC cache allocated in the first pool has a static size, and wherein the portion of the SLC cache allocated in the second pool has a dynamic size;
determine a difference in normalized wear between the first and second pools satisfies a wear threshold criterion; and
prioritizing the second pool for a first SLC write in response to the difference in normalized wear satisfying the wear threshold criterion.

17. The system of claim 16, wherein the processing device is further configured to determine if the second pool includes an available block allocated to the SLC cache.

18. The system of claim 17, wherein the available block is utilized in the second pool if the second pool includes the available block allocated to the SLC cache.

19. The system of claim 17, wherein prioritizing the second pool includes allocating another block to the second pool for the SLC write in response to determining the second pool and the first pool do not include the available block.

20. The system of claim 17, wherein prioritizing the second pool includes utilizing an available block is utilized in the first pool in response to determining the second pool does not include the available block.
